(19) United States
(12) Patent Application Publication
(10) Pub. No.: US 2010/0200863 A1
(43) Pub. Date: Aug. 12, 2010

(54) ELECTRODE STRUCTURE, SEMICONDUCTOR DEVICE, AND METHODS FOR MANUFACTURING THOSE

(75) Inventors: Tatsuya Sasaki, Tokyo (JP); Kazuhiro Shiba, Tokyo (JP); Shigeru Koumoto, Tokyo (JP); Masayoshi Sumino, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 11/917,124

(22) PCT Filed: Jul. 6, 2006
(86) PCT No.: PCT/JP2006/313482

§ 371 Date: Dec. 10, 2007

(30) Foreign Application Priority Data
Jul. 8, 2005 (JP) 2005-200894

(51) Int. Cl. H01L 29/40; H01L 21/20; H01L 21/28

(52) U.S. Cl. 257/76; 438/478; 438/585; 257/E21.19; 257/E21.09; 257/E29.111

(57) ABSTRACT

A first layer containing Ti as a constituent element, a second layer containing Nb as a constituent element, and a third layer containing Au as a constituent element are formed on a GaN substrate 11. Thereafter, the GaN substrate 11 and the first to third layers are kept at 700° C. or higher and at 1300° C. or lower. This allows a metal oxide of Ti to be distributed to extend from the interface between the GaN substrate 11 and the electrode 14 over to the inside of the electrode 14. Further, a metal nitride of Nb is formed in the inside of the GaN substrate 11. The metal nitride of Nb will be distributed to extend from the inside of the electrode 14 over to the inside of the GaN substrate 11.

### TECHNICAL FIELD

The present invention relates to an electrode structure using a nitride semiconductor layer.

### BACKGROUND ART

In nitride semiconductor devices such as a semiconductor laser and a light-emitting diode, it is an important technical goal to form an electrode structure exhibiting a good ohmic contact.

A patent document 1 discloses a semiconductor laser in which an n-side electrode having a laminate structure made of a plurality of metal layers is disposed on a nitride semiconductor layer. As disclosed in claim 1 of the patent document 1, the n-side electrode of this semiconductor laser has a layer made of Ti formed on the nitride semiconductor layer, an uppermost layer made of Au, and a layer containing Nb disposed between the layer made of Ti and the aforementioned uppermost layer, and is subjected to heat treatment at 400° C. or higher (for example, 600° C.) together with the nitride semiconductor layer.

The n-side electrode disclosed in the patent document 1 is intended to obtain a good ohmic contact between the layer made of Ti and the nitride semiconductor layer.

In the patent document 1, the hydrogen atoms having penetrated into the n-type GaN layer are expelled by the heat treatment of the n-side electrode and the n-type GaN layer at 400° C. or higher (for example, 600° C.). By expelling the hydrogen atoms, it is considered that a good ohmic contact is attained between the layer made of Ti of the n-side electrode and the nitride semiconductor layer.

In addition to this, in the patent document 1, the layer containing Nb prevents diffusion of Au to the nitride semiconductor layer side during the heat treatment, thereby preventing deterioration of the ohmic contact. Namely, in the electrode of the patent document 1, the layer containing Nb functions as a barrier layer.

### [Patent Document 1] Japanese Patent No. 3239350

### DISCLOSURE OF THE INVENTION

However, in recent years, a further reduction of the driving current and the driving voltage of a semiconductor device is demanded, thereby inviting a situation in which a further more reduction of the contact resistance between the nitride semiconductor layer and the n-side electrode is demanded. According to the conventional technique such as disclosed in the patent document 1, it is difficult to realize an electrode structure that meets such a demand.

Into the inside of the electrode structure, O atoms are mingled inevitably. Regarding the electrode disclosed in the above-described patent document 1, it seems that the O atoms and the Ti atoms constituting the electrode are bonded at the interface between the nitride semiconductor layer and the electrode, thereby forming a metal oxide. This metal oxide has a low electric conductivity. Therefore, it is inferred that, when the maximum concentration position in the concentration distribution of the metal oxide is present at the interface between the nitride semiconductor layer and the electrode or in the vicinity of the interface, the contact resistance between the electrode and the nitride semiconductor layer rises, giving a cause for inhibiting the reduction of the contact resistance.

According to the present invention, there is provided an electrode structure including: a nitride semiconductor layer; and an electrode disposed on this nitride semiconductor layer, wherein the nitride semiconductor layer contains a metal nitride containing Nb, Hf, or Zr as a constituent element, a metal oxide containing Ti or V as a constituent element is distributed to extend from the interface between the nitride semiconductor layer and the electrode over to the inside of the electrode, and a content of the metal oxide at a maximum concentration position of a concentration distribution of the metal oxide is 30% or less, and the maximum concentration position is located in an inner side of the electrode than a vicinity of the interface with said nitride semiconductor layer of said electrode.

Also, according to the present invention, there is provided an electrode structure including: a nitride semiconductor layer; and an electrode disposed on this nitride semiconductor layer, wherein the nitride semiconductor layer contains a metal nitride containing Nb, Hf, or Zr as a constituent element, a metal oxide containing Ti or V as a constituent element is distributed to extend from the interface between the nitride semiconductor layer and the electrode over to the inside of the electrode, and a maximum concentration position of a concentration distribution of the metal oxide is located in an inner side of the electrode than a vicinity of the interface with said nitride semiconductor layer of said electrode.

Here, the content of the metal oxide at the maximum concentration position refers to the ratio of the constituent element as detected by an Auger spectroscopy or a secondary ion mass spectrometer at the maximum concentration position.

The metal oxide contained in the electrode of the present invention is distributed to extend from the interface between the nitride semiconductor layer and the electrode over to the inside of the electrode, and the maximum concentration position of the concentration distribution of the metal oxide is located in an inner side of the electrode than a vicinity of the interface between the nitride semiconductor layer and the electrode (the vicinity refers to a range from the interface between the electrode and the nitride semiconductor layer to 1/10 of the thickness of the electrode). In this manner, according to the present invention, the metal oxide is diffused, the maximum concentration position in the concentration distribution of the metal oxide is absent at the interface between the electrode and the nitride semiconductor layer or in the vicinity of the interface. Therefore, one can prevent the rise in the contact resistance between the electrode and the nitride semiconductor layer caused by the metal oxide. This can achieve reduction of the contact resistance between the electrode and the nitride semiconductor layer.

Further, by setting the content of the metal oxide at the maximum concentration position to be 30% or less, the reduction of the contact resistance between the electrode and the nitride semiconductor layer can be achieved with more certainty.

Here, the content of the metal oxide at the maximum concentration position is preferably 20% or less, still more preferably 10% or less.

In addition to this, by the metal nitride in the nitride semiconductor layer, N holes where N atoms are absent are formed in the nitride semiconductor layer, thereby increasing the electron concentration. This reduces the contact resistance between the electrode and the nitride semiconductor layer, whereby an ohmic contact with a low resistance can be obtained with certainty.

Here, in order to reduce the contact resistance between the electrode and the nitride semiconductor layer with certainty, it is preferable that the N holes are formed at the interface between the nitride semiconductor layer and the electrode or in the vicinity of the interface.

Therefore, the metal nitride is preferably formed to be diffused to extend from the interface between the nitride semiconductor layer and the electrode to a vicinity of the interface (for example, a range from the interface to the position located at 5 nm inside the nitride semiconductor layer).

Also, according to the present invention, there is provided a semiconductor device provided with the electrode structure described above.

Further, according to the present invention, there can be provided a method of forming an electrode structure having a nitride semiconductor layer and an electrode disposed on this nitride semiconductor layer, including: forming a first layer containing Ti or V as a constituent element on the nitride semiconductor layer; forming a second layer containing Nb, Hf, or Zr as a constituent element on the first layer; and performing a heat treatment of at least the nitride semiconductor layer, the first layer, and the second layer at 700° C. or higher and at 1300° C. or lower.

Here, the nitride semiconductor layer may be a substrate.

According to the present invention, the nitride semiconductor layer, the first layer, and the second layer are subjected to a heat treatment at 700° C. or higher and at 1300° C. or lower. Therefore, the atoms of Ti or V (hereafter referred to as Ti or the like) of the first layer are bonded principally to the O atoms that are present at the interface between the nitride semiconductor layer and the electrode (the O atoms that are bonded to the nitride semiconductor layer surface). The metal oxide of Ti or the like produced by the bonding of the atoms of Ti or the like with the O atoms will be diffused from the interface between the nitride semiconductor layer and the electrode to the inside of the electrode by the heat treatment. For this reason, a metal oxide having a high concentration will be absent in the vicinity of the interface with the nitride semiconductor layer of the electrode, whereby the contact resistance between the nitride semiconductor layer and the electrode can be reduced.

On the other hand, the atoms such as Nb, Hf, or Zr (hereafter referred to as Nb or the like) of the second layer are bonded to the N atoms of the nitride semiconductor layer, thereby forming a metal nitride in the nitride semiconductor layer. By this, N holes where N atoms are absent are formed in the nitride semiconductor layer, thereby increasing the electron concentration. When the electron concentration increases, the contact resistance between the electrode and the nitride semiconductor layer is reduced, whereby an ohmic contact having a lower resistance can be obtained.

As described above, the layer containing Nb in the patent document 1 functions as a barrier layer that prevents diffusion of Au contained in the uppermost layer into the n-type GaN layer. For this reason, it seems that the Nb atoms themselves will not enter the n-type GaN layer (nitride semiconductor layer) by the heat treatment.

Here, in the patent document 1, there is a possibility such that the Ti atoms of the layer made of Ti enter the n-type GaN layer (nitride semiconductor layer), whereby the Ti atoms and the N atoms are bonded. However, the Ti atoms of the layer made of Ti are bonded also to the oxygen atoms at the interface between the n-type GaN layer and the electrode. Therefore, the Ti atoms and the N atoms are not efficiently bonded with each other, so that, according to the technique of the patent document 1, one cannot form a sufficient number of N holes in the nitride semiconductor layer. Therefore, it is difficult to achieve reduction of the contact resistance between the electrode and the nitride semiconductor layer.

In contrast, in the present invention, the atoms of Ti or the like of the first layer are principally bonded to the O atoms that are present at the interface between the nitride semiconductor layer and the electrode, and the atoms of Nb or the like of the second layer are intentionally diffused into the nitride semiconductor layer. By this diffusion of the atoms of Nb or the like, a sufficient number of N holes are formed in the nitride semiconductor layer, thereby achieving reduction of the contact resistance between the electrode and the nitride semiconductor layer.

Here, in the heat treatment step, the N atoms in the nitride semiconductor layer are dissociated after the O atoms are dissociated from the surface of the nitride semiconductor layer. In the event that the electrode is formed by disposing only the second layer without disposing the first layer, Nb or the like of the second layer is first bonded to the O atoms to form a metal oxide of Nb or the like. This metal oxide of Nb or the like, which is produced at the interface between the electrode and the nitride semiconductor layer, has a property of being hardly diffused. Therefore, even if a heat is added by the heat treatment, the metal oxide of Nb or the like moves little from the interface between the electrode and the nitride semiconductor layer. For this reason, the diffusion of the atoms of Nb or the like that are not bonded to the O atoms to the nitride semiconductor layer side will be inhibited by the metal oxide of Nb or the like that is present at the interface between the electrode and the nitride semiconductor layer.

Therefore, it will be difficult to produce a metal nitride by bonding of the atoms of Nb or the like to the N atoms in the nitride semiconductor layer, whereby one cannot form a sufficient number of N holes in the nitride semiconductor layer. This makes it difficult to sufficiently reduce the contact resistance between the electrode and the nitride semiconductor layer.

In contrast, in the present invention, the first layer containing Ti or the like and the second layer containing Nb or the like are provided. The bonding between the O atoms in the surface of the nitride semiconductor layer and the Ti or the like of the first layer is generated, whereby a metal oxide of Ti or the like is produced. This metal oxide of Ti or the like is diffused by the heat treatment to extend from the interface over to the inside of the electrode. The diffusion of the atoms of Nb or the like to the nitride semiconductor layer side is not inhibited by the metal oxide of Ti or the like, and the atoms of Nb or the like enters the inside of the nitride semiconductor layer. For this reason, a metal nitride by the bonding between the atoms of Nb or the like and the N atoms can be produced in the nitride semiconductor layer, whereby a sufficient number of N holes can be formed in the nitride semiconductor layer. Therefore, the contact resistance between the electrode and the nitride semiconductor layer can be sufficiently reduced.

Further, according to the present invention, there can also be provided a method of manufacturing a semiconductor device, including forming a multiple-layer film containing an active layer on a nitride semiconductor substrate; selectively removing a surface of the multiple-layer film and the nitride semiconductor substrate; disposing a first electrode on an etched surface of the nitride semiconductor substrate to form an electrode structure; forming a second electrode on the multiple-layer film, wherein, in the forming the electrode structure, the electrode structure is formed by the method described above.

According to the present invention, the contact resistance can be reduced, and an ohmic contact having a low resistance can be ensured.

### BRIEF DESCRIPTION OF THE DRAWINGS

The aforementioned objects as well as other objects, features, and advantages will be made more apparent by the preferable embodiments described below and the following drawings accompanying thereto.

FIG. 1 is a cross-sectional view of a semiconductor laser according to the first embodiment of the present invention.

FIGS. 2(A) and 2(B) are schematic views showing steps for manufacturing the semiconductor laser of the first embodiment.

FIGS. 3(C) and 3(D) are schematic views showing steps for manufacturing the semiconductor laser of the first embodiment.

FIG. 4(E) is a schematic view showing a step for manufacturing the semiconductor laser of the first embodiment.

FIG. 5 is a view showing a relationship between the bond energy with nitrogen atoms and the bond energy with oxygen atoms

FIG. 6 is a cross-sectional view of a semiconductor laser according to the second embodiment of the present invention.

FIG. 7 is a cross-sectional view of a semiconductor laser according to a modification of the present invention.

FIG. 8 is a cross-sectional view of a semiconductor laser according to another modification of the present invention.

FIG. 9 is a view showing a relationship between the heat treatment temperature and the voltage between the n-side electrode and the p-side electrode.

FIG. 10 is a view showing a concentration distribution of atoms in an electrode structure that has not been subjected to a heat treatment.

FIG. 11 is a view showing a concentration distribution of atoms in an electrode structure that has been subjected to a heat treatment of 400° C.

FIG. 12 is a view showing a concentration distribution of atoms in an electrode structure that has been subjected to a heat treatment at 800° C.

FIG. 13 is a view showing results of observation by an electron microscope of the cross section of the electrode structure that has been subjected to a heat treatment at 800° C.

### BEST MODES FOR CARRYING OUT THE INVENTION

Hereafter, embodiments of the present invention will be described with use of the drawings. Here, in all of the drawings, like constituent elements will be denoted with like reference numerals, and the description will not be repeated.

### First Embodiment

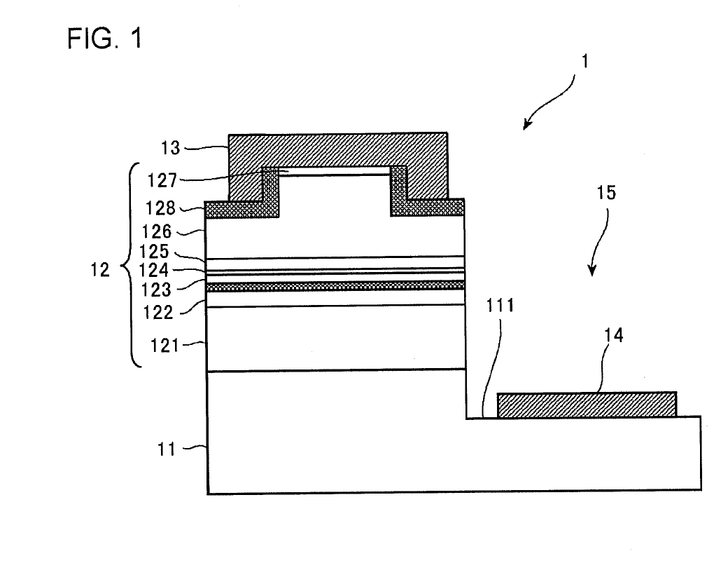

FIG. 1 is a cross-sectional view of a semiconductor laser (semiconductor device) 1 according to the present embodiment.

The semiconductor laser 1 includes an n-type GaN substrate 11 serving as a nitride semiconductor layer, a multiple-layer film 12 formed on this GaN substrate 11, a p-side electrode 13 (second electrode) formed on the multiple-layer film 12, and an n-side electrode 14 (first electrode) formed on the GaN substrate 11.

The GaN substrate 11 is approximately L-shaped in its cross section, where a part of the surface of the flat-plate-shaped substrate has been removed by dry etching. The n-side electrode 14 is formed on the etched surface 111 of this GaN substrate 11.

The multiple-layer film 12 is formed on the (0001) surface (what is known as a Ga surface) of the GaN substrate 11, and includes an n-type AlGaN clad layer 121, an n-type GaN guide layer 122, an InGaN quantum well active layer 123 that oscillates a laser beam, a p-type AlGaN electron overflow prevention layer 124, a p-type GaN guide layer 125, a p-type AlGaN clad layer 126, a p-type GaN contact layer 127, and an insulating film 128.

A ridge part that extends along the resonator direction (the direction approximately parallel to the laser beam emission direction) is formed in the AlGaN clad layer 126.

The GaN contact layer 127 is formed at the top part of this ridge part. The p-side electrode 13 is formed so as to be in contact with the surface of this GaN contact layer 127.

Also, the insulating film 128 which is an SiO₂ film is formed on the side surface of the ridge part and on the surface of the clad layer 126 adjacent to the ridge part.

The n-side electrode 14 also is formed on the (0001) surface of the GaN substrate 11. This n-side electrode 14 and the GaN substrate 11 constitute the electrode structure 15 of the present invention.

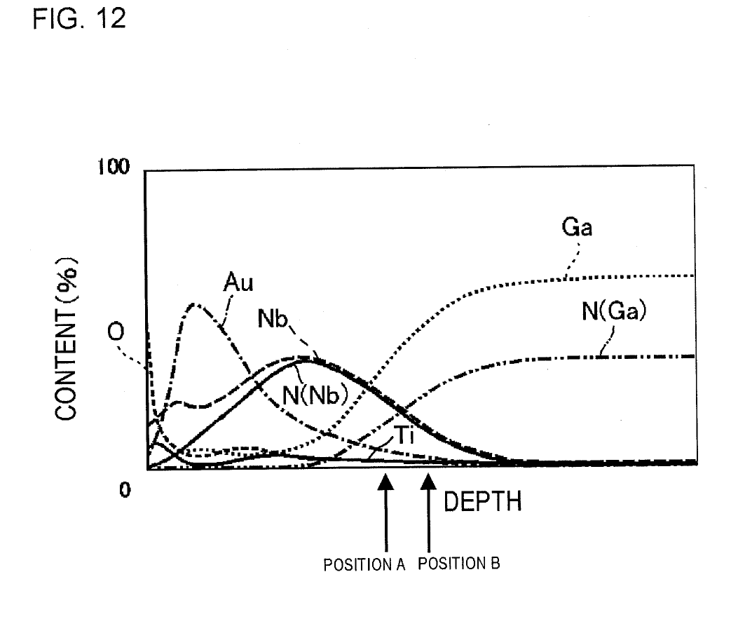

The electrode 14 is a layer in which plural kinds of metals are made into an alloy. The details thereof will be described in the Examples given later. As exemplified in FIG. 12, the content of Au increases along the direction from the lower side (the etched surface 111 side of the GaN substrate 11) to the upper side. Au is contained in the uppermost surface of this electrode 14 (the upper surface of the electrode 14 in FIG. 1). FIG. 12 is a view showing a concentration distribution of the atoms of the electrode and the GaN substrate that have been subjected to a heat treatment at 800° C. In this FIG. 12, the lateral axis represents the depth of the electrode structure, where the right side in FIG. 12 is the GaN substrate side, and the left side in FIG. 12 is the electrode side.

Also, as exemplified in FIG. 12, the electrode 14 contains a metal oxide containing Ti as a constituent element (a metal oxide of Ti in the present embodiment).

The metal oxide of Ti is distributed to extend from the interface between the electrode 14 and the GaN substrate 11 over to the uppermost layer of the electrode 14. Also, the maximum concentration position in the concentration distribution of the metal oxide of Ti is located in an inner side of the electrode 14 than a vicinity (the position A in FIG. 12) of the interface with the GaN substrate 11 of the electrode 14.

Here, the vicinity of the interface refers to a range from the interface between the electrode 14 and the GaN substrate 11 to 1/10 of the thickness of the electrode 14.

Further, the content of the metal oxide of Ti is 30% or less. Here, the content at the maximum concentration position refers to the ratio of the constituent element as detected by an Auger spectroscopy or a secondary ion mass spectrometer at the maximum concentration position. Also, the maximum concentration of the metal oxide of Ti is 1×10²² cm⁻³ or less.

Further, the electrode 14 contains a metal nitride containing Nb as a constituent element (a metal oxide of Nb in the present embodiment). The metal nitride of Nb is distributed to extend from the electrode 14 over to the GaN substrate 11 surface (namely, the interface between the electrode 14 and the GaN substrate 11) and further over to the GaN substrate 11. Therefore, the metal nitride is present also in the inside of the GaN substrate 11, whereby the GaN substrate 11 contains the metal nitride. As shown in FIG. 12, the metal nitride of Nb is distributed to extend from the interface between the GaN substrate 11 and the electrode 14, over the vicinity of the interface of the GaN substrate 11 (the position down to 5 nm from the interface (the position B of FIG. 12)) to the inside of the GaN substrate 11.

Also, in forming the electrode 14, Al may be contained as a metal material; however, the driving voltage of the semiconductor laser 1 may rise by oxidation of Al.

For this reason, in forming the electrode 14, it is preferable that Al is not mixed with the metal material, and the electrode 14 substantially does not contain Al.

Here, the expression “the metal electrode 14 substantially does not contain Al” means that, intentionally, Al is not added into the electrode 14, and is a concept including a case in which Al enters inevitably.

Next, a method of manufacturing the semiconductor laser 1 as shown above will be described.

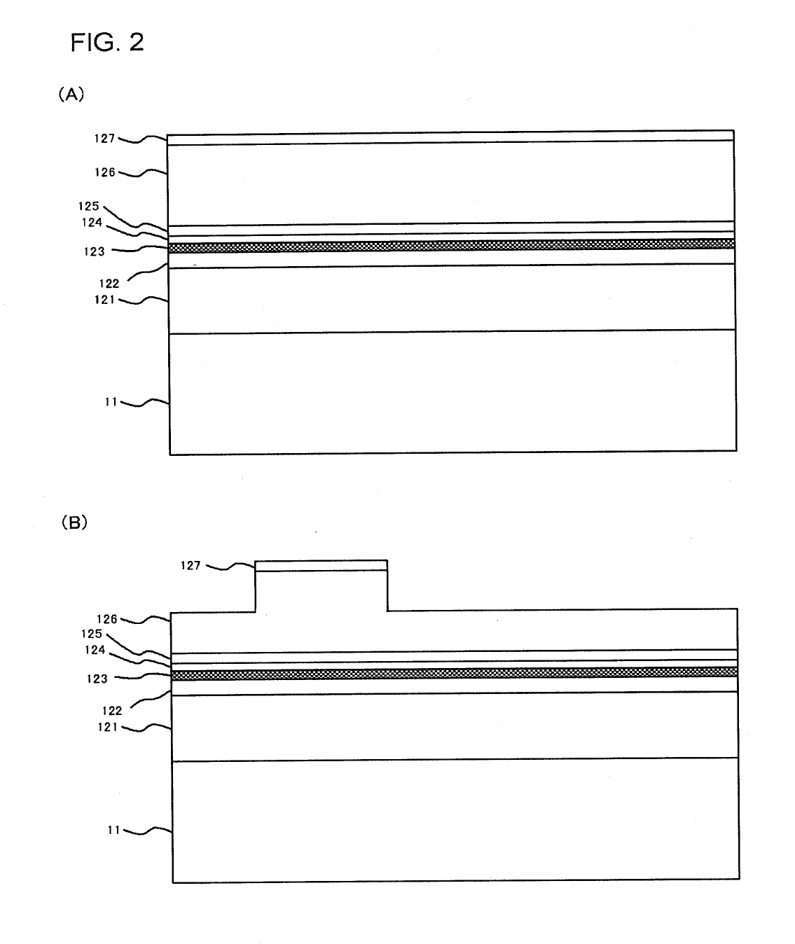

First, as shown in FIG. 2(A), an n-type AlGaN clad layer 121, an n-type GaN guide layer 122, an InGaN quantum well active layer 123, a p-type AlGaN electron overflow prevention layer 124, a p-type GaN guide layer 125, a p-type AlGaN clad layer 126, and a p-type GaN contact layer 127 are formed on a GaN substrate 11. The method of forming each of the layers 121 to 127 is not particularly limited; however, they can be formed, for example, by the MOCVD method (metal organic chemical vapor deposition method).

Next, a mask of SiO₂ film (not illustrated) that covers a part of the surface of the p-type GaN contact layer 127 is formed on the p-type GaN contact layer 127. This mask extends in the resonator direction of the semiconductor laser.

Thereafter, apart of the p-type GaN contact layer 127 and the p-type AlGaN clad layer 126 is selectively removed by dry etching. This forms a ridge part (See FIG. 2(B)). Here, a gas containing chlorine is used as an etchant for the dry etching.

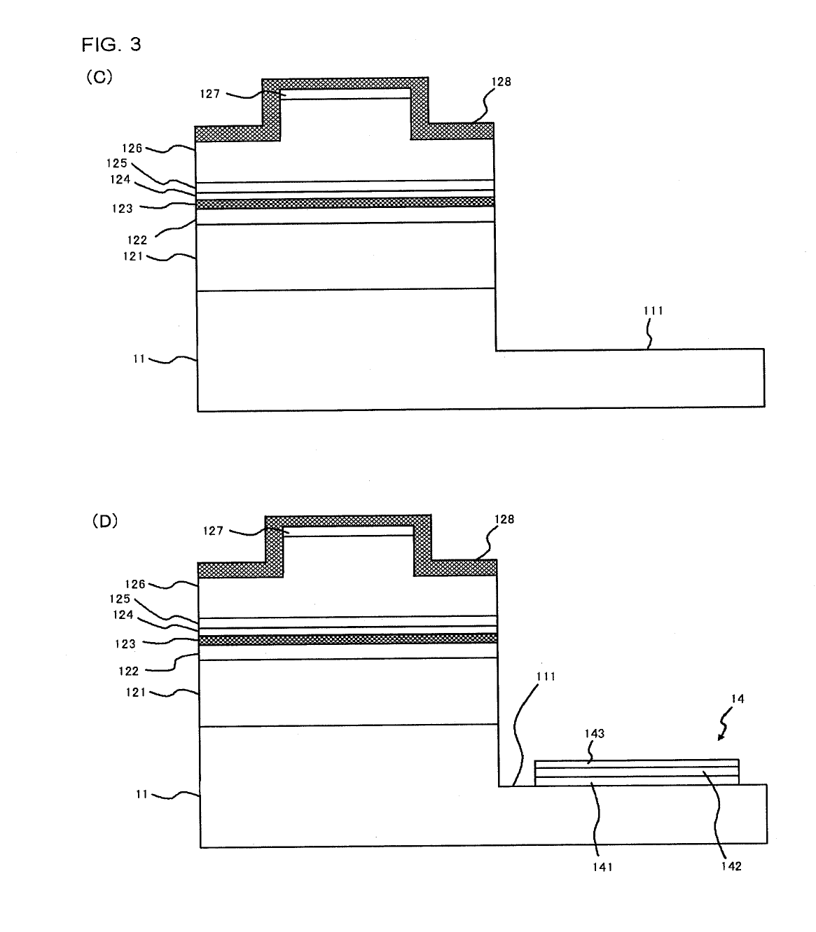

Next, the ridge part of the AlGaN clad layer 126 and a vicinity of this ridge part are covered with a mask of the insulating film 128 which is an SiO₂ film, and the part where the insulating film 128 is not formed is selectively removed by dry etching. The etching here is carried out until apart of the surface of the GaN substrate 11 is removed (FIG. 3(C)).

Next, an n-side electrode 14 is formed on the etched surface 111 of the GaN substrate 11 that has been exposed by the dry etching.

First, as shown in FIG. 3(D), a first layer 141 containing Ti as a constituent element is formed on the etched surface 111 of the GaN substrate 11. In the present embodiment, metals other than Ti are intentionally not added into the first layer 141 and the first layer 141 is a layer constituted of Ti.

The thickness of the first layer 141 is preferably 4 nm or more and 15 nm or less.

In the heat treatment step described later, the O atoms that are present in the etched surface 111 of the GaN substrate 11 (the interface between the GaN substrate 11 and the electrode 14) and the Ti atoms constituting the first layer 141 are bonded so as to form a metal oxide of Ti, and the O atoms are diffused from the etched surface 111 of the GaN substrate 11. However, when the first layer 141 is set to be less than 4 nm, the number of Ti atoms will be extremely small as contrasted with the O atoms, thereby causing a case in which the O atoms cannot be sufficiently diffused from the etched surface 111.

Also, in the heat treatment step described later, the Nb atoms of the second layer 142 mentioned later penetrate into the inside of the GaN substrate 11 so as to form a metal nitride of Nb. When the thickness of the first layer 141 is set to exceed 15 nm, there may be a case in which the metal nitride of Nb is hardly formed.

Next, a second layer 142 is formed on the first layer 141. The second layer 142 is a layer containing Nb as a constituent element. In the present embodiment, metals other than Nb are intentionally not added into the second layer 142 and the second layer 142 is a layer constituted of Nb.

Further, a third layer 143 constituted of Au or an alloy containing Au (for example, an alloy of Au and Ag) is formed on the second layer 142.

These layers of the first layer 141 to the third layer 143 can be formed by vapor deposition.

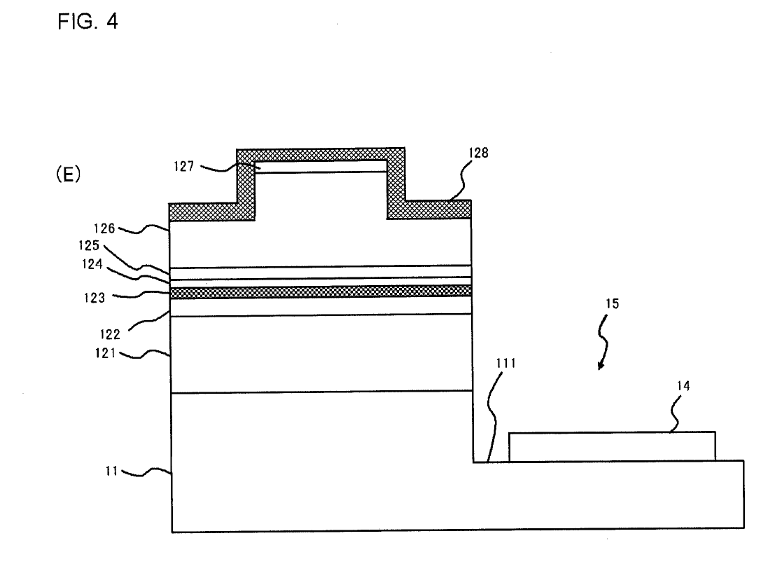

Thereafter, the GaN substrate 11 on which the electrode 14 has been formed is subjected to a heat treatment at 700° C. or higher and at 1300° C. or lower in an nitrogen atmosphere (FIG. 4(E)).

Here, with reference to the profile exemplified in FIG. 12, the effect of the heat treatment will be described in detail.

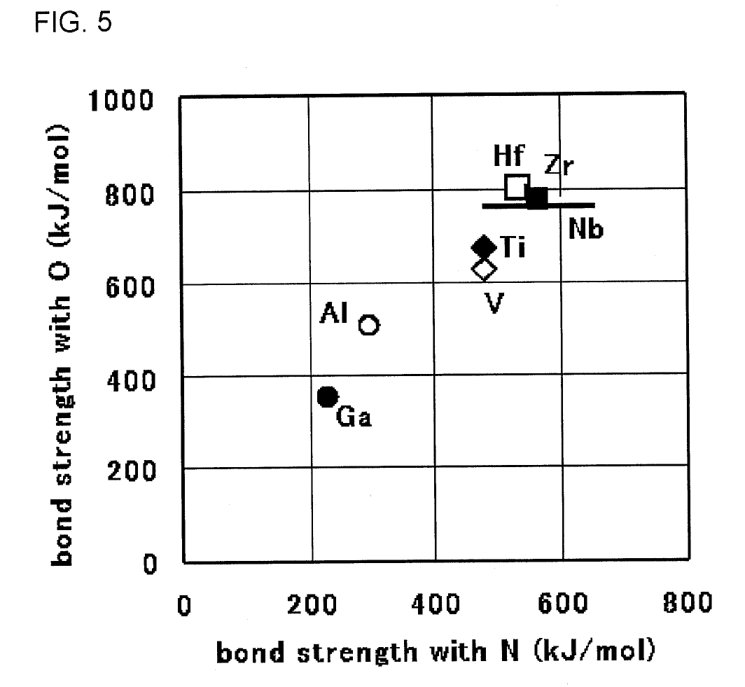

When the GaN substrate 11 on which the electrode 14 has been formed is heated, first the O atoms are eliminated from the etched surface 111 of the GaN substrate 11, and the O atoms are bonded to the Ti atoms of the first layer 141 located on the GaN substrate 11. As shown in FIG. 5, since the Ti atoms have a higher bond energy to the O atoms than the Ga atoms, the O atoms are bonded to the Ti atoms.

The metal oxide of Ti obtained by the bonding of the Ti atoms and the O atoms is produced at the interface between the electrode 14 and the GaN substrate 11; however, in accordance with the heat treatment, the metal oxide of Ti will be diffused from the interface towards the upper part of the electrode 14.

Next, when the heat treatment further proceeds, the Nb atoms of the second layer 142 will be diffused down into the inside of the GaN substrate 11.

Here, when one sees the profile of FIG. 12, it will be understood that the Nb atoms have penetrated down into the inside of the GaN substrate 11. Therefore, it seems that the diffusion of the Nb atoms is hardly inhibited by the metal oxide of Ti.

The N atoms are eliminated from the GaN substrate 11, and the N atoms are bonded to the Nb atoms. This forms a metal nitride in the inside of the GaN substrate 11. This metal nitride is distributed to extend from the GaN substrate 11 surface to the inside of the GaN substrate 11.

Here, the N atoms that have been eliminated from the GaN substrate 11 are diffused also to the second layer 142 side, so that the metal nitride of Nb will be distributed also in the inside of the electrode 14.

By the bonding of the Nb atoms and the N atoms, N holes are formed at the interface between the GaN substrate 11 and the electrode 14 and in the vicinity of the interface in the inside of the GaN substrate 11. By these N holes, the contact resistance between the electrode 14 and the GaN substrate 11 can be reduced.

Here, it seems that the N atoms of the GaN substrate 11 are bonded not only to the Nb atoms of the second layer 142 but also to the Ti atoms of the first layer 141. However, as shown in FIG. 5, the Nb atoms have a higher bond energy to the N atoms than the Ti atoms, so that the bonding of the Nb atoms to the N atoms will be preferentially carried out. Since the Nb atoms are hardly consumed for bonding to the O atoms that are present in the GaN substrate 11 surface (the O atoms that are present at the interface between the GaN substrate 11 and the electrode 14), a large number of Nb atoms can be used for bonding to the N atoms.

This can form a sufficient number of N holes in the inside of the GaN substrate 11.

Here, since the dissociation energy of the Ti atoms of the first layer 141 from the O atoms will be an extremely high value, it seems that a phenomenon in which the O atoms are eliminated from the metal oxide of Ti to be bonded again to the Nb atoms of the second layer 142, will not occur.

Here, it is sufficient that the heat treatment temperature is 700° C. or higher and 1300° C. or lower; however, among this, the heat temperature is preferably 800° C. or higher and 1300° C. or lower. By setting it to be 800° C. or higher, the bonding between the N atoms of the GaN substrate 11 and the Nb atoms of the second layer 142 is promoted, whereby the contact resistance between the electrode 14 and the GaN substrate 11 can be further reduced.

Here, the reason why the heat treatment temperature is set to be 1300° C. or lower is as follows. When the heat treatment temperature exceeds 1300° C., it will exceed the melting point of the GaN substrate 14.

Also, when the heat treatment temperature is set to be less than 700° C., a sufficient number of N holes cannot be formed in the GaN substrate 11 because the diffusion of the Nb atoms of the second layer 142 will be insufficient.

Next, the insulating film 128 on the ridge part is opened to expose the p-type GaN contact layer 127, and a p-side electrode 13 is formed on the surface. Thereafter, a heat treatment is carried out (for example, the heat treatment is carried out at 400° C. for 15 minutes). Further, the back surface of the GaN substrate 11 is polished.

The above process completes the semiconductor laser 1.

Hereafter, the effects of the present embodiment will be described.

In the present embodiment, the GaN substrate 11 having the n-side electrode 14 disposed thereon is subjected to a heat treatment at 700° C. or higher and at 1300° C. or lower, so that the Ti contained in the first layer 141 is mainly bonded to the O atoms of the interface between the GaN substrate 11 and the electrode 14 (namely, the etched surface 111 of the GaN substrate 11). The metal oxide produced by this bonding of Ti with the O atoms will be diffused towards the upper part of the electrode 14.

Then, the content of the metal oxide at the maximum concentration position of the concentration distribution of the metal oxide will be 30% or less, and the maximum concentration position will exist in an inner side of the electrode 14 than the vicinity of the interface with the GaN substrate 11 of the electrode 14.

By such diffusion of the metal oxide, the maximum concentration position of the concentration distribution of the metal oxide will not exist at the interface with the electrode 14 of the GaN substrate 11 and in the vicinity of the interface, and further, a metal oxide having a high concentration will not exist at the interface with the electrode 14 of the GaN substrate 11 and in the vicinity of the interface, thereby achieving reduction of the contact resistance between the GaN substrate 11 and the electrode 14.

In particular, in the present embodiment, the surface of the GaN substrate 11 on which the electrode 14 is to be formed is an etched surface 111 subjected to dry etching so that an extremely large number of O atoms seem to be present. For this reason, a metal oxide having a high concentration will be formed at the interface between the GaN substrate 11 and the electrode 14. In the present embodiment, the metal oxide is diffused to extend from the interface over to the inside of the electrode 14 so that the contact resistance between the GaN substrate 11 and the electrode 14 can be effectively reduced.

Also, by the heat treatment at 700° C. or higher and at 1300° C. or lower, the Nb contained in the second layer 142 will be diffused to the interface between the GaN substrate 11 and the electrode 14 and further to the inside of the GaN substrate 11 so as to be mainly bonded to the N atoms of the GaN substrate 11. This forms a metal nitride in the inside of the electrode 14, and further extending from the interface between the GaN substrate 11 and the electrode 14 over to the inside of the GaN substrate 11. For this reason, N holes where N atoms are absent are formed at the interface between the GaN substrate 11 and the electrode 14 and in the vicinity of the interface of the GaN substrate 11, thereby increasing the electron concentration at the interface with the electrode 14 of the GaN substrate 11 and in the vicinity of the interface. When the electron concentration increases, the contact resistance between the electrode 14 and the GaN substrate 11 lowers, whereby one can obtain an ohmic contact with a lower resistance.

Here, it seems that the diffusion of the Nb atoms is inhibited little by the metal oxide of Ti so that in the present embodiment, the Nb atoms can be diffused into the inside of the GaN substrate 11 with certainty.

As described above, in the present embodiment, N holes are formed in the GaN substrate 11, and also the metal oxide at the interface between the GaN substrate 11 and the electrode 14 is diffused, so that the contact resistance between the electrode 14 and the GaN substrate 11 can be sufficiently reduced.

Further, in the present embodiment, it is assumed that Au is contained in the uppermost surface of the electrode 14. When the uppermost surface of the electrode 14 contains Au, the inside of the electrode 14 can be protected. Also, when the uppermost surface of the electrode 14 contains Au, the wire for connecting the electrode 14 to an external leading line can be bonded to the electrode 14 with certainty.

Further, when an electrode containing Al as a major component is formed, Al may be deteriorated by heat generation when the semiconductor laser is operated at a high output for a long period of time. By this deterioration of Al, the contact resistance will be high, whereby the driving voltage of the semiconductor laser fluctuates, and the long-term reliability of the semiconductor laser will be low.

In contrast, in the present embodiment, the electrode 14 substantially does not contain Al, and further a material (Ti, Nb, Au) that is hardly deteriorated by heat generation is used to construct the electrode 14. Therefore, the deterioration of the electrode 14 is hardly generated even if the semiconductor laser 1 is operated at a high output for a long period of time, whereby the semiconductor laser 1 will have a high long-term reliability.

Also, in the present embodiment, in manufacturing the semiconductor laser 1, each of the layers 121 to 127 is formed on the GaN substrate 11, and thereafter a part of each of the layers 121 to 126 and a part of the surface of the GaN substrate 11 are subjected to dry etching. In order to remove a part of the layers 121 to 126 so as not to etch the GaN substrate 11, the etching condition must be highly controlled; however, in the present embodiment, since apart of the surface of the GaN substrate 11 is removed also, the etching condition need not be highly controlled.

Further, in the present embodiment, the p-side electrode 13 and the n-side electrode 14 are formed on the (0001) surface of the GaN substrate 11, where the p-side electrode 13 is formed after the n-side electrode 14 is formed. The heat treatment temperature of the p-side electrode 13 is lower than the heat treatment temperature of the n-side electrode 14. Therefore, by forming the p-side electrode 13 after forming the n-side electrode 14, the p-side electrode 13 is prevented from being affected by the heat treatment of the n-side electrode 14.

Also, in the present embodiment, the first layer 141 of the n-side electrode 14 is a layer constituted of Ti. Since the layer constituted of Ti is excellent in the close adhesion property with the GaN substrate 11, the first layer 141 can be prevented from being released from the GaN substrate 11.

### Second Embodiment

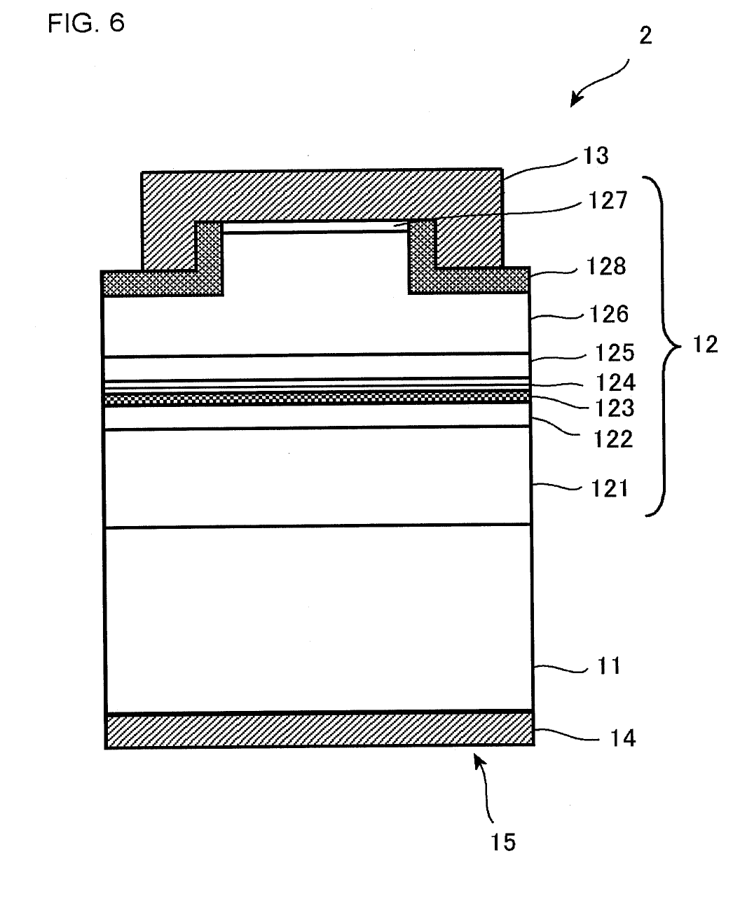

With reference to FIG. 6, a semiconductor laser 2 of the second embodiment will be described.

In the aforementioned second embodiment, the n-side electrode 14 and the p-side electrode 13 are formed on the (0001) surface of the GaN substrate 11. In the present embodiment, the n-side electrode 14 is formed on the (000-1) surface (what is known as an N surface) of the GaN substrate 11. The other points are the same as in the above embodiment.

In producing the semiconductor laser 2, the n-side electrode 14 and the p-side electrode 13 must be subjected to a heat treatment as in the aforementioned embodiment.

Here, when the heat treatment temperature of the p-side electrode 13 is lower than the heat treatment temperature of the n-side electrode 14, the heat treatment of the n-side electrode 14 is preferably carried out before the heat treatment of the p-side electrode 13. In the case of performing the heat treatment of the n-side electrode 14 before the heat treatment of the p-side electrode 13, the GaN substrate 11 may be bonded onto a supporting substrate to form the p-side electrode 13 after forming the n-side electrode 14 and performing the heat treatment of the n-side electrode 14.

Here, the heat treatment of the n-side electrode 14 may be carried out after the heat treatment of the p-side electrode 13 is carried out.

For example, after forming the p-side electrode 13 on the surface ((0001) surface) of the GaN substrate 11 and performing the heat treatment, the back surface ((000-1) surface of the GaN substrate 11 is polished. Thereafter, the n-side electrode 14 is formed on the back surface of the GaN substrate 11, and only the back surface side of the GaN substrate 11 is selectively subjected to a heat treatment at 700° C. or higher and at 1300° C. or lower. In this case, only the back surface side of the GaN substrate 11 can be selectively heated at 700° C. or higher and at 1300° C. or lower by using laser anneal, flash lamp anneal, or the like.

According to the present embodiment such as this, the n-side electrode 14 is formed on a surface of the GaN substrate 11 opposite to the surface on which the p-side electrode 13 has been formed, whereby a larger surface for forming the n-side electrode 14 can be ensured. For example, the n-side electrode 14 can be formed on the entire surface of the opposite surface, whereby the contact resistance can be further reduced as compared with a case in which the n-side electrode 14 is formed on the surface on which the p-side electrode 13 has been formed as in the first embodiment.

Also, since the (000-1) surface of the GaN substrate 11 is a polished surface, it seems that also an organic impurity is present in addition to the O atoms on the (000-1) surface of the GaN substrate 11. In the heat treatment step, not only the O atoms but also the inorganic impurity will be bonded to Ti constituting the electrode 14 and will be incorporated into the inside of the electrode 14, thereby preventing increase of the contact resistance between the electrode 14 and the GaN substrate 11.

As shown above, the embodiments of the present invention have been described; however, these are an exemplification of the present invention and various constructions other than the above can be adopted as well.

For example, in each of the above embodiments, the first layer 141 of the electrode 14 is a layer constituted of Ti; however, the present invention is not limited to this alone and the first layer 141 may be a layer constituted of V. In this case, a metal oxide of V will be present in the inside of the electrode 14 after the heat treatment.

The V atoms have approximately the same degree of bond energy with the O atoms and bond energy with the N atoms as the Ti atoms as shown in FIG. 5. Therefore, even in the case in which the first layer 141 is a layer constituted of V, the V atoms will be bonded to the O atoms in the same manner as the Ti atoms, so as to form a metal oxide in the inside of the electrode 14 after the heat treatment.

Also, the first layer may be a layer containing Ti and V as constituent elements.

Here, it is sufficient that the first layer contains Ti or V as a constituent element, and may contain other metal elements.

However, since the layer in which the first layer is constituted of Ti is excellent in the close adhesion property to the nitride semiconductor substrate, the first layer is preferably a layer constituted of Ti.

Further, in the above-described embodiments, the second layer 142 of the electrode 14 is a layer constituted of Nb; however, the present invention is not limited to this alone and the second layer 142 may be a layer constituted of Hf or Zr. As shown in FIG. 5, the Hf atoms and the Zr atoms have approximately the same degree of bond energy with the O atoms and bond energy with the N atoms as the Nb atoms. Therefore, even in the case in which the second layer 142 is a layer constituted of Hf or Zr, the Hf or Zr atoms will be bonded to the N atoms in the same manner as the Nb atoms, so as to form a metal nitride of Hf or a metal nitride of Zr in the inside of the GaN substrate 11 or in the inside of the electrode 14 after the heat treatment.

Here, since Nb is more excellent in thermal stability than Hf or Zr, the second layer 142 is preferably a layer constituted of Nb.

Further, the second layer 142 may be a layer containing two or more kinds of metals among Nb, Hf, and Zr as constituent elements.

Here, it is sufficient that the second layer contains Nb, Hf, or Zr as a constituent element, and may contain other metal elements.

By arbitrarily selecting the constituent element of the first layer from Ti and V and further arbitrarily selecting the constituent element of the second layer from Nb, Hf, and Zr, an effect similar to that of each of the above-described embodiments can be produced.

In each of the above-described embodiments, a metal nitride of Nb is contained in the inside of the electrode 14 after the heat treatment; however, the present invention is not limited to this and the metal nitride of Nb need not be contained in the inside of the electrode 14.

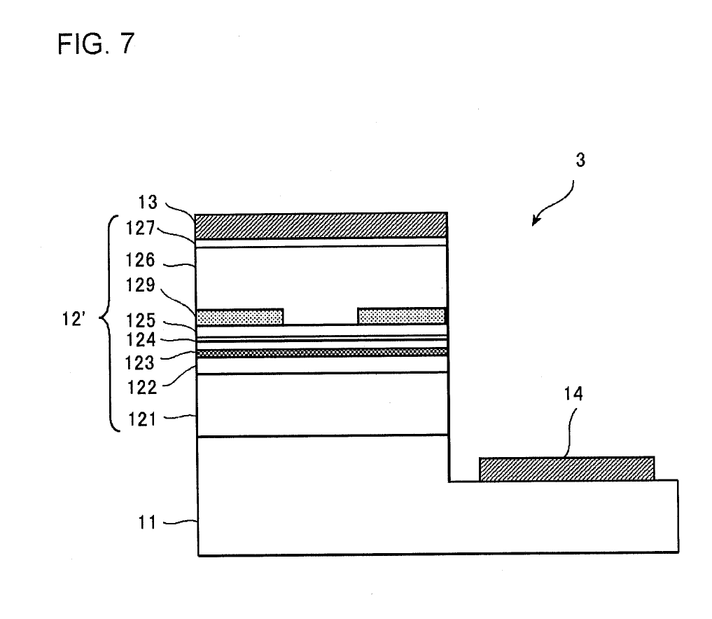

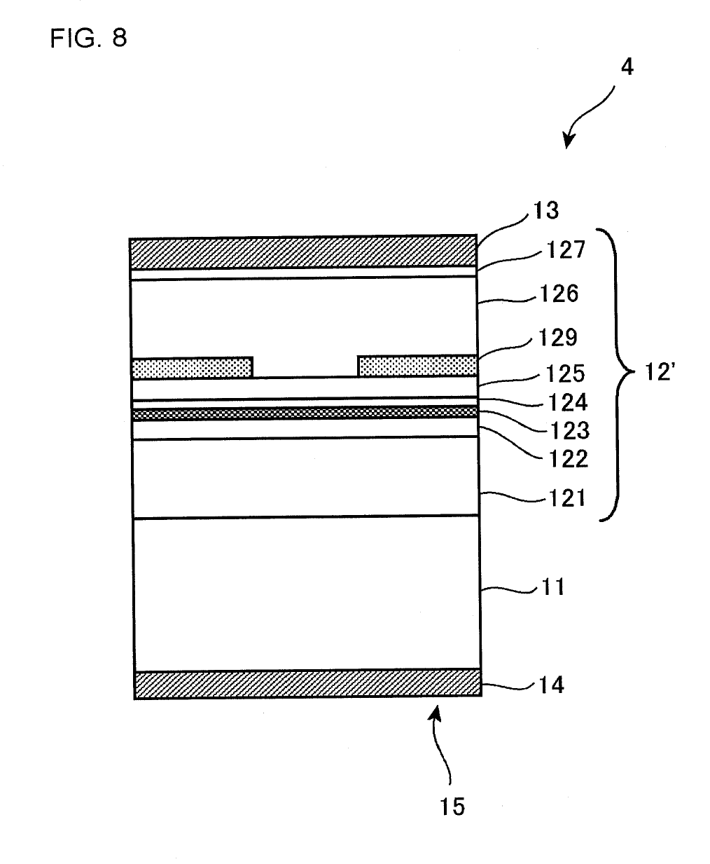

Also, in each of the above-described embodiments, a ridge part is formed in the p-type AlGaN clad layer 126; however, the present invention is not limited to this and the ridge part need not be formed. For example, the semiconductor laser may be a semiconductor laser having an inner stripe structure such as a semiconductor laser 3 shown in FIG. 7 or a semiconductor laser 4 shown in FIG. 8.

In producing the semiconductor laser 3 or 4, an n-type AlGaN clad layer 121, an n-type GaN guide layer 122, an InGaN quantum well active layer 123, a p-type AlGaN electron overflow prevention layer 124, a p-type GaN guide layer 125, and an AlN block layer 129 are laminated on a surface of a GaN substrate 11, and then the center of the AlN block layer 129 is removed by etching with use of a mask of SiO₂ film, so as to form an electric passageway part.

Thereafter, a p-type AlGaN clad layer 126 and a p-type GaN contact layer 127 are grown. Thereafter, an n-side electrode 14 and a p-side electrode 13 are formed by a method similar to that of each of the above-described embodiments.

In a semiconductor laser 3 or 4 such as this, the AlN block layer 129 has an electric current narrowing function and a light beam enclosing function, there is no need to form a ridge part.

Also, the semiconductor lasers 1 and 2 of each of the above embodiments are representative examples, and the layer structure is not limited to the one mentioned in each of the above embodiments.

For example, in each of the above embodiments, the clad layer 126 is a layer constructed with AlGaN; however, the present invention is not limited to this alone and the clad layer 126 may be a superlattice clad made of AlGaN/GaN. This can effectively reduce the driving voltage of the semiconductor laser.

Further, in each of the above embodiments, the GaN substrate 11 may be used as a nitride semiconductor substrate for the semiconductor lasers 1 and 2; however, the present invention is not limited to this alone and it may be a nitride semiconductor substrate containing In or Al as a group III element. Also, it may be a BN substrate or the like.

Also, the electrode structure of the present invention is not limited to the one in which an electrode is directly formed on a substrate. For example, a GaN substrate may be formed as a nitride semiconductor layer on a sapphire substrate, and an electrode may be formed on this GaN layer.

Further, in the above embodiments, the semiconductor lasers 1 and 2 are shown as semiconductor devices to which the electrode structure of the present invention is applied; however, the present invention is not limited to them, a light-emitting diode or the like may be used.

Also, the semiconductor device is not limited to a light-emitting device, and it may be a photoreceptive device.

Further, the electrode structure of the present invention may be applied to an electron device such as a field effect type transistor (FET). In the event that the electrode structure of the present invention is applied to a field effect type transistor (FET) or the like, an electrode may be formed on a surface of an AlGaN (having an Al composition ratio of about 0.2 to 0.4) substrate.

### EXAMPLES

A semiconductor laser similar to that of the first embodiment was produced, and the relationship between the heat treatment temperature of the electrode structure and the voltage was studied.

Specifically, a multiple-layer film similar to that of the first embodiment was formed on a GaN substrate, and further an n-side electrode was formed. Here, the first layer of the n-side electrode was set to be a layer constituted of Ti; the second layer was set to be a layer constituted of Nb; and the third layer was set to be a layer constituted of Au. The thickness of the second layer was set to be 50 nm, and the thickness of the third layer was set to be 100 nm. Also, the film thickness of the first layer was varied within a range of 5 to 100 nm, so as to form 6 kinds of n-side electrodes.

Thereafter, the GaN substrate on which the n-side electrode had been formed was subjected to a heat treatment at different temperatures, and a p-side electrode was formed.

The voltage between the n-side electrode and the p-side electrode at each of the heat treatment temperatures was measured. Here, the heat treatment was carried out in a nitrogen atmosphere.

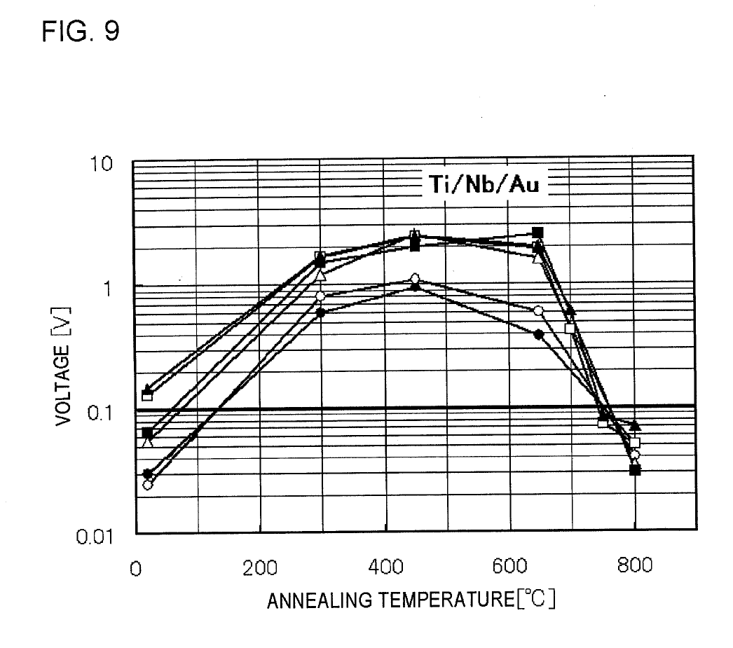

The results are shown in FIG. 9.

In FIG. 9, the black triangular point represents one in which the film thickness of the first layer is 100 nm; the white quadrangular point represents one in which the film thickness of the first layer is 5 nm; the black quadrangular point represents one in which the film thickness of the first layer is 50 nm; the white triangular point represents one in which the film thickness of the first layer is 30 nm; the black circular point represents one in which the film thickness of the first layer is 10 nm; and the white circular point represents one in which the film thickness of the first layer is 15 nm.

With reference to FIG. 9, it will be understood that, until the heat treatment temperature reaches 300° C., the voltage rises sharply. Also, it will be understood that, when the heat treatment temperature is from 300° C. to 650° C., the voltage rises gradually. Further, it will be understood that, when the heat treatment temperature reaches 700° C. or higher, the voltage goes down.

In the Examples of the above-described patent document 1, the heat treatment of the electrode structure is carried out at 600° C. With reference to FIG. 9, it has been found out that the electrode structure of the present invention subjected to a heat treatment at 700° C. or higher gives a lower resistance value than the conventional electrode structure disclosed in the patent document 1.

Here, for practical use, in order to obtain a sufficiently low contact resistance, it is preferable that the voltage value shown in FIG. 9 is 0.1 V or less. Therefore, the heat treatment temperature is more preferably 750° C. or higher.

Next, the relationship between the heat treatment temperature of the electrode structure including the n-side electrode and the GaN substrate and the concentration distribution of the atoms constituting the electrode structure was studied.

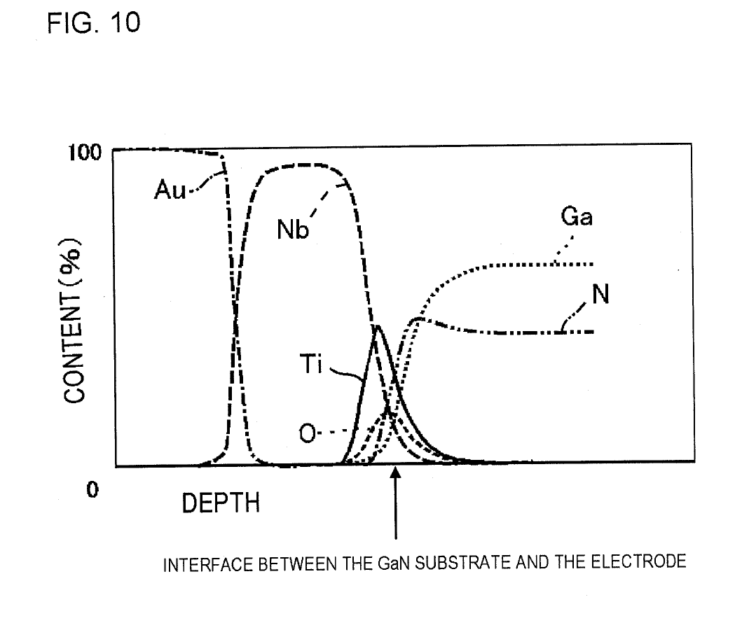

First, a first layer (layer constituted of Ti, film thickness: 5 nm), a second layer (layer constituted of Nb, film thickness: 50 nm), and a third layer (layer constituted of Au, film thickness: 100 nm) were disposed on a GaN substrate, so as to form an electrode structure. Then, an Auger spectroscopy spectrum was evaluated in three electrode structures made of an electrode structure that has not been subjected to a heat treatment, an electrode structure subjected to a heat treatment at 400° C., and an electrode structure subjected to a heat treatment at 800° C., so as to confirm the concentration distribution of the atoms constituting the electrode structure. The results are shown in FIGS. 10 to 12.

Here, in FIGS. 10 to 12, the lateral axis represents the depth of the electrode structure, where the right side in the drawings represents the GaN substrate side, and the left side in the drawings represents the electrode side.

FIG. 10 shows a concentration distribution of the atoms of the electrode structure that has not been subjected to a heat treatment.

In the electrode structure that has not been subjected to a heat treatment, it can be confirmed that a first layer constituted of Ti, a second layer constituted of Nb, and a third layer constituted of Au are laminated on a GaN substrate. Also, it will be understood that O atoms are present at a high concentration at the interface between the GaN substrate and the electrode.

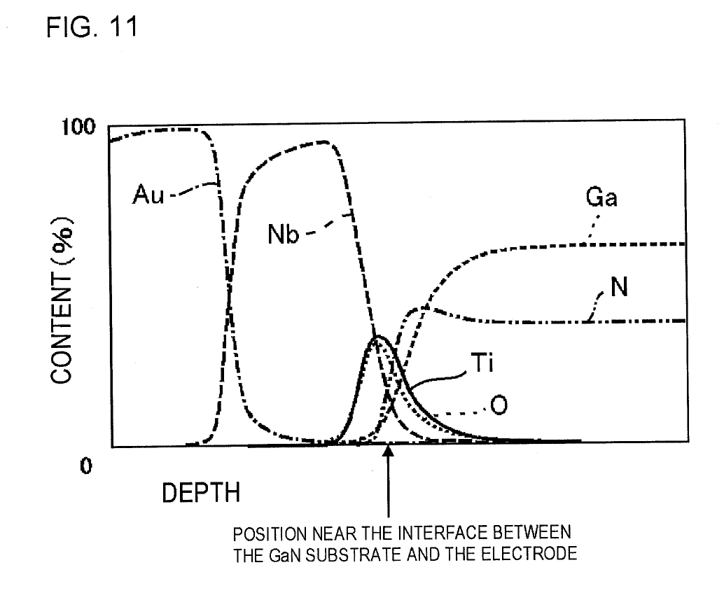

FIG. 11 shows a concentration distribution of the atoms of the electrode structure that has been subjected to a heat treatment at 400° C. It will be understood that the O atoms at the interface between the GaN substrate and the electrode are bonded to the Ti atoms of the first layer so as to form a metal oxide. This metal oxide is present to be concentrated in the vicinity of the interface between the GaN substrate and the electrode. The maximum concentration position of this metal oxide is in the vicinity of the interface, and the content at the maximum concentration position of the metal oxide exceeds 30%.

In FIG. 9, the reason why the voltage rises sharply near 300° C. seems to be that the O atoms in the GaN substrate surface are bonded to the Ti atoms of the first layer, and the metal oxide having a low electric conductivity has been formed at a high concentration in the vicinity of the interface with the electrode of the GaN substrate.

FIG. 12 shows the concentration distribution of the electrode structure that has been subjected to a heat treatment at 800° C. It will be understood that, in the electrode structure subjected to a heat treatment at 800° C., the atoms of Nb of the second layer are diffused to the interface between the GaN substrate and the electrode and further to the inside of the GaN substrate, thereby forming a metal nitride of Nb.

In FIG. 12, the N bonded to Ga and the N bonded to Nb are displayed to be separated from each other, and are displayed as N(Ga) and N(Nb), respectively. The profile of N(Ga) goes along the profile of Ga, and the profile of N(Nb) approximately coincides with the profile of Nb on the interface side.

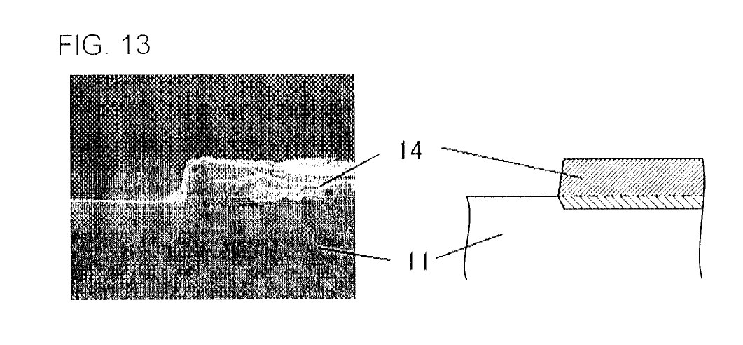

Also, FIG. 13 shows an observation result by an electron microscope of the cross section of the electrode structure that has been subjected to a heat treatment at 800° C. By this observation result as well, it has been confirmed that, by the heat treatment at 800° C., the atoms of Nb have penetrated into the inside of the GaN substrate, whereby the metal nitride of Nb is formed to extend from the GaN substrate surface over to the inside of the GaN substrate.

In the schematic view on the right side of FIG. 13, the cross-hatched part in the inside of the GaN substrate 11 represents the metal nitride of Nb.

Also, with reference to FIG. 12 again, it will be understood that the O atoms that were present in the GaN substrate surface are principally bonded to Ti atoms to form a metal oxide of Ti. In addition, it will be understood that this metal oxide of Ti is present to extend from the interface between the electrode and the GaN substrate to the inside of the electrode. The maximum concentration position in the concentration distribution of the metal oxide of Ti is in the vicinity of the interface, and the content at the maximum concentration position of the metal oxide was 30% or less (10% or less in FIG. 12). Further, the maximum concentration, position in the distribution of the metal oxide of Ti was located in an inner side of the electrode than the vicinity of the interface with the GaN substrate of the electrode.

Also, the maximum concentration of the metal oxide of Ti was 1×10²² cm⁻³ or less.

As described above, it seems that, by the heat treatment of 800° C., the Nb atoms penetrate into the inside of the GaN substrate, whereby N holes are formed in the inside of the GaN substrate, and also the metal oxide that was present at the interface between the GaN substrate and the electrode is diffused, so that the voltage lowered to a great extent as shown in FIG. 9.

Here, the effect of reduction of the resistance by the heat treatment can be recognized when the content at the maximum concentration position of the metal oxide of Ti subsequent to the heat treatment is 30% or less. When the content is 20% or less, the decrease in the voltage is further considerable (the voltage between the n-side electrode and the p-side electrode is 0.2 V or less). Further, when the content is 10% or less as in FIG. 12, the voltage between the n-side electrode and the p-side electrode was 0.1 V or less, whereby a practically sufficient low-voltage operation could be realized with a good reproducibility.

Next, the relationship between the heat treatment and the contact resistance in an electrode structure in which the electrode was formed without disposing the first layer was studied.

To be more specific, a second layer (50 nm) constituted of Nb and a third layer (100 nm) constituted of Au were disposed, without disposing a first layer, on a GaN substrate on which a multiple-layer film similar to that of the first embodiment had been formed. Then, the multiple-layer film, the GaN substrate, the second layer, and the third layer were subjected to a heat treatment at 800° C. in a nitrogen atmosphere, and thereafter, a p-side electrode was formed to obtain a semiconductor laser.

The voltage between the n-side electrode and the p-side electrode of this semiconductor laser was measured. In this case, the voltage became extremely high, although a heat treatment at 800° C. was carried out.

The Auger spectroscopy spectrum of the n-side electrode and the GaN substrate of this semiconductor laser was evaluated, whereby it was confirmed that a metal oxide of Nb was present at the interface between the electrode and the GaN substrate. Also, Nb had been hardly diffused into the inside of the GaN substrate, and the metal nitride of Nb could not be confirmed here.

In this manner, in the event that the second layer is formed on the GaN substrate without forming the first layer on the GaN substrate, it seems that the metal oxide of Nb is present at the interface between the electrode and the GaN substrate thereby to inhibit the diffusion of the Nb atoms to the GaN substrate side. For this reason, it seems that a sufficient number of N holes cannot be formed in the inside of the GaN substrate, and reduction of the contact resistance between the electrode and the GaN substrate cannot be achieved.

In contrast, when the first layer constituted of Ti, the second layer constituted of Nb, and the third layer constituted of Au are formed on the GaN substrate as shown in FIG. 12, it seems that the diffusion of the Nb atoms to the GaN substrate side is not inhibited by the metal oxide of Ti, and a metal nitride of Nb is formed in the inside of the GaN substrate. For this reason, it seems that N holes can be formed in the inside of the GaN substrate, whereby one can achieve reduction of the contact resistance between the electrode and the GaN substrate can be achieved.

1-18. (canceled)

19. An electrode structure comprising:
a nitride semiconductor layer; and
an electrode disposed on this nitride semiconductor layer, wherein
said nitride semiconductor layer contains a metal nitride containing Nb, Hf, or Zr as a constituent element, and
a metal oxide containing Ti or V as a constituent element is formed in a part of said electrode.

20. The electrode structure as set forth in claim 19, wherein
a maximum concentration position of a concentration distribution of said metal oxide is located in an inner side of said electrode than a vicinity of an interface with said nitride semiconductor layer of said electrode.

21. The electrode structure as set forth in claim 20, wherein
a concentration of said metal oxide at the maximum concentration position of the concentration distribution of said metal oxide is 30% or less of the total atoms at said maximum concentration position.

22. The electrode structure as set forth in claim 19, wherein
said metal nitride is a nitride of the metal element diffused from said electrode.

23. The electrode structure as set forth in claim 19, wherein
said metal nitride is distributed also in the inside of said electrode.

24. The electrode structure as set forth in claim 19, wherein
said metal nitride is formed to extend from the surface of said nitride semiconductor layer over to the inside of the nitride semiconductor layer.

25. The electrode structure as set forth in claim 19, wherein
said metal oxide is formed by bonding of Ti or V serving as a constituent element of said electrode with oxygen atoms at the interface between said nitride semiconductor layer and said electrode and being diffused from said interface to the inside of the electrode.

26. The electrode structure as set forth in claim 19, wherein
said nitride semiconductor layer contains a metal nitride of Nb.

27. The electrode structure as set forth in claim 19, wherein
said electrode contains a metal oxide of Ti.

28. The electrode structure as set forth in claim 19, wherein
Au is contained in the surface of said electrode.

29. The electrode structure as set forth in claim 19, wherein
said nitride semiconductor layer has a surface subjected to dry etching, and
said electrode is disposed on the dry-etched surface of said nitride semiconductor layer.

30. The electrode structure as set forth in claim 19, wherein
said nitride semiconductor layer is a GaN substrate.

31. The electrode structure as set forth in claim 30, wherein
said electrode is disposed on a (0001) surface of said GaN substrate.

32. The electrode structure as set forth in claim 30, wherein
said electrode is disposed on a (000-1) surface of said GaN substrate.

33. The electrode structure as set forth in claim 19, wherein
said electrode substantially does not contain Al.

34. The electrode structure as set forth in claim 19, wherein
said nitride semiconductor layer contains a metal nitride of Nb, and
said electrode contains a metal oxide of Ti.

35. The electrode structure as set forth in claim 19, wherein
Au is contained in the surface of said electrode, and
said electrode substantially does not contain Al.

36. An electrode structure comprising:
a nitride semiconductor layer; and
an electrode disposed on this nitride semiconductor layer, wherein
said nitride semiconductor layer contains a metal nitride containing Nb, Hf, or Zr as a constituent element,
a metal oxide containing Ti or V as a constituent element is distributed to extend from the interface between said nitride semiconductor layer and said electrode over to the inside of said electrode, and
a maximum concentration position of a concentration distribution of said metal oxide is located in an inner side of said electrode than a vicinity of the interface with said nitride semiconductor layer of said electrode.

37. A semiconductor device comprising the electrode structure as set forth in claim 19.

38. A method of forming an electrode structure comprising a nitride semiconductor layer and an electrode disposed on this nitride semiconductor layer, comprising:
forming a first layer containing Ti or V as a constituent element on said nitride semiconductor layer;
forming a second layer containing Nb, Hf, or Zr as a constituent element on said first layer; and
performing a heat treatment of at least said nitride semiconductor layer, said first layer, and said second layer at 700° C. or higher and at 1300° C. or lower.

39. The method of forming an electrode structure as set forth in claim 38, wherein,
in said heat treatment, Ti or V of said first layer is bonded to oxygen atoms at the interface between said nitride semiconductor layer and said electrode to form a metal oxide; this metal oxide is diffused into the inside of said electrode; and Nb, Hf, or Zr serving as the constituent element of said second layer is diffused into said nitride semiconductor layer to form a metal nitride.

40. A method of manufacturing a semiconductor device, comprising:
forming a multiple-layer film containing an active layer on a nitride semiconductor substrate;
selectively removing a surface of said multiple-layer film and said nitride semiconductor substrate;
disposing a first electrode on an etched surface of said nitride semiconductor substrate to form an electrode structure;
forming a second electrode on said multiple-layer film, wherein,
in said forming the electrode structure, the electrode structure is formed by the method as set forth in claim 38.

41. A method of manufacturing a semiconductor device, comprising:
forming a multiple-layer film containing an active layer on a nitride semiconductor substrate;
selectively removing a surface of said multiple-layer film and said nitride semiconductor substrate;
disposing a first electrode on an etched surface of said nitride semiconductor substrate to form an electrode structure;
forming a second electrode on said multiple-layer film, wherein,
in said forming the electrode structure, the electrode structure is formed by the method as set forth in claim 39.
